(19) United States
(12) Patent Application Publication
(10) Pub. No.: US 2014/0264181 A1
(43) Pub. Date: Sep. 18, 2014

(54) Thermoplastic Resin Composition Having Excellent EMI Shielding Property

(71) Applicant: Cheil Industries Inc., Gumi-si (KR)

(72) Inventors: Chan Gyun Shin, Uiwang-si (KR); Kyung Rae Kim, Uiwang-si (KR); Jung Wook Kim, Uiwang-si (KR); Jong Cheol Lim, Uiwang-si (KR); Byung Kuk Jeon, Uiwang-si (KR)

(73) Assignee: Cheil Industries Inc., Gumi-si (KR)

(21) Appl. No.: 14/183,580

(22) Filed: Feb. 19, 2014

(30) Foreign Application Priority Data
Mar. 15, 2013 (KR) 10-2013-0027764

(51) Int. Cl. H05K 9/00

(52) U.S. Cl. CPC H05K 9/009
USPC 252/478

(57) ABSTRACT

A thermoplastic resin composition includes (A) about 50 to about 90% by weight of a crystalline thermoplastic resin having a melting point of about 200 to about 380° C.; and (B) about 10 to about 50% by weight of a filler in which a carbon nanostructure having an average length of about 1 to about 1000 μm and an average diameter of about 1 to about 100 nm is grown on a glass fiber surface. The thermoplastic resin composition can have excellent EMI shielding property and/or fluidity.

### CROSS-REFERENCE TO RELATED APPLICATION

This application claims priority under 35 USC Section 119 to and the benefit of Korean Patent Application No. 10-2013-0027764, filed Mar. 15, 2013, the entire disclosure of which is incorporated herein by reference.

### FIELD OF THE INVENTION

The present invention relates to thermoplastic resin composition that can have excellent EMI shielding property.

### BACKGROUND OF THE INVENTION

Electromagnetic wave pollution has been increasing steadily in daily life, because electromagnetic waves have higher frequency hands due to the multifunctionality/miniaturization of electrical/electronic products, and the development of information and communication devices. Due to this phenomenon, emitted electromagnetic waves may cause malfunctions and system errors in surrounding devices and damage to the human body. Therefore, the demand for EMI shielding technology, which could effectively prevent these problems, is increasing.

Conventional EMI shielding technologies include metal products and metal plated conductible membrane. However, if a metal product has a complex shape or pattern, processability can deteriorate. Also, metal products are heavy. Further, plating metal onto a conductible membrane can require complex processes such as degreasing, etching, neutralizing, activating, depositing metal, plating, should be performed, which can reduce productivity. Also, over time, desorption of metal based materials can occur, so there can be a problem with stability of usage.

In contrast, polymer composite resins used as electrical conducting and EMI shielding materials may have advantages in terms of production cost and processability, because they can be used in injection molding processes to make a product. In order to improve EMI shielding efficiency, carbon fibers, metal powders, metal fibers, magnetic materials, dielectric materials or conductive materials are used in resin.

Korean Patent Publication 2010-080419 discloses a resin composition comprising thermoplastic resin, inorganic materials and fiber fillers. Korean Patent Publication 2011-0079103 discloses a resin composition comprising thermoplastic resin, inorganic fillers and metals. The fillers, however, have poor dispersibility, so it can be difficult to achieve the desired EMI shielding efficiency.

### SUMMARY OF THE INVENTION

The present invention provides a thermoplastic resin composition that can have excellent EMI shielding property. The present inventors have developed a thermoplastic resin composition that can have excellent EMI shielding property by using a filler in which a carbon nanostructure is grown on a glass fiber surface.

The present invention also provides a thermoplastic resin composition that can have excellent fluidity. The present invention further provides a thermoplastic resin composition that can have excellent injection moldability. The present invention further provides a thermoplastic resin composition that can have excellent mechanical strength such as impact strength and flexural modulus.

A thermoplastic resin composition in accordance with the present invention may comprise (A) about 50 to about 90% by weight of a crystalline thermoplastic resin having melting point of about 200 to about 380° C.; and (B) about 10 to about 50% by weight of a filler in which a carbon nanostructure having an average length of about 1 to about 1000 μm and an average diameter of about 1 to about 100 nm is grown on a glass fiber surface.

The crystalline thermoplastic resin (A) may be polyphenylene sulfide resin and/or a polyamides resin having a benzene ring as a part of its main chain. The crystalline thermoplastic resin (A) may further comprise a liquid crystal polymer. The liquid crystal polymer can include para-azoxyanisole (PAA), para-methoxybenzylidene-para-butylaniline (MBBA), terephthalic acid (TA), para-hydroxybenzoic acid (HBA), hydroquinone (HQ), 6-hydroxy-2-naphtoic acid (HNA) or a combination thereof.

The glass fiber may have a ratio of the minor axis of the cross section to the major axis of the cross section of about 1:1.5 to about 1:10.

The carbon nanostructure may include carbon nanotubes, for example, double wall carbon nanotubes and/or multi wall carbon nanotubes.

The thermoplastic resin composition of the present invention may further comprise magnetic materials, dielectric materials, conductive materials or a combination thereof.

Also, the thermoplastic resin composition of the present invention may further comprise one or more additives such as antimicrobials, releasing agents, heat stabilizers, antioxidants, photostabilizers, compatibilizers, dyes, inorganic additives, surfactants, nucleating agents, coupling agents, plasticizers, impact modifiers, admixtures, colorants, stabilizers, lubricants, antistatic agents, pigments, flame proofing agents or a combination thereof.

An EMI shielding article in accordance with the present invention may be prepared from the thermoplastic resin composition.

The present invention can provide thermoplastic resin composition that can have excellent EMI shielding property, fluidity, injection moldability and mechanical strength.

### DETAILED DESCRIPTION OF THE INVENTION

The present invention now will be described more fully hereinafter in the following detailed description of the invention in which some but not all embodiments of the invention are described. Indeed, this invention may be embodied in many different forms and should not be construed as limited to the embodiments set forth herein; rather, these embodiments are provided so that this disclosure will satisfy applicable legal requirements.

The present invention relates to a thermoplastic resin composition that can have excellent EMI shielding property. More particularly, the present invention relates to a thermoplastic resin composition that can have excellent EMI shielding property using a filler in which a carbon nanostructure is grown on a glass fiber surface.

The thermoplastic resin composition of the present invention may comprise (A) about 50 to about 90% by weight of a crystalline thermoplastic resin having a melting point of about 200 to about 380° C. and (B) about 10 to about 50% by weight of a filler in which carbon nanostructure is grown on a glass fiber surface, wherein the carbon nanostructure has an average length of about 1 to about 1000 μm and an average diameter of about 1 to about 100 nm, and the glass fiber has an average length of about 0.1 to about 30 mm and average diameter of about 1 to about 30 μm.

### (A) Crystalline Thermoplastic Resin

In the present invention, a crystalline thermoplastic resin (A) may be used as the thermoplastic resin. In the case of the crystalline thermoplastic resin, during crystallization of the thermoplastic resin, a filler is excluded from crystalline regions, so the crystalline thermoplastic resin may have excellent conductivity and reinforcement effect compared with a non-crystalline thermoplastic resin. The crystalline thermoplastic resin (A) having a melting point of about 200 to about 380° C. may be used without limitation. When the crystalline thermoplastic resin (A) has a melting point within the above range of melting point, the crystalline thermoplastic resin may have excellent heat resistance.

Examples of the crystalline thermoplastic resin (A) having a melting point of about 200 to about 380° C. can include without limitation polyphenylene sulfide resins and/or polyamide resins having a benzene ring as a part of its main chain.

The polyphenylene sulfide resin has high heat resistance, and simultaneously at a temperature of −50° C. it maintains physical properties as if at a room temperature, and it has excellent dimensional stability and creep resistance throughout the wide temperature range. Also, the polyphenylene sulfide resin is non-toxic and safe, has excellent flame retardancy, and has relatively low viscosity, so it is suitable for use in a polymer composite resin.

In exemplary embodiments, the polyphenylene sulfide resin can be a linear polyphenylene sulfide resin comprising about 50 mole % or more, for example about 70 mole % or more, of a repeating unit represented by Chemical Formula 1, based on 100 mole % of the repeating units making up the polyphenylene sulfide resin:

[chemical structure]

If the polyphenylene sulfide resin comprises about 50 mole % or more of the repeating unit represented by Chemical Formula 1, it can have a high degree of crystallization, and also can have excellent heat resistance, chemical resistance and strength. Japanese Patent Publication 1977-12240 discloses a representative preparing method for a linear polyphenylene sulfide resin comprising the repeating unit represented by Chemical Formula 1.

In exemplary embodiments, the polyphenylene sulfide resin may further comprise about 50 mole % or less, for example about 30 mole % or less, of a repeating unit that is different from Chemical Formula 1, based on 100 mole % of the repeating units making up the polyphenylene sulfide resin. Examples of repeating units that are different from Chemical Formula 1 are represented by the following Chemical Formulas 2 to 9.

[chemical structure]

In the Chemical Formula 7, R is alkyl group, nitro group, phenyl group, alkoxy group, carboxyl group, or carboxylate salt group.

[chemical structure]

In exemplary embodiments, a polymer comprising about 50 mole % or more of repeat units derived from p-dichlorobenzene and produced by the reaction of p-dichlorobenzene and sodium sulfide may be used as the polyphenylene sulfide resin.

The polyphenylene sulfide resin can have a low viscosity. If viscosity of the polyphenylene sulfide resin is low, high filling of the heat conductive inorganic filler is favorable, so a complex having high heat conductivity can be prepared.

To provide low viscosity, the polyphenylene sulfide resin may have a weight average molecular weight of about 3,000 to about 50,000 g/mol, for example about 5,000 to about 30,000 g/mol. When the polyphenylene sulfide resin has a weight average molecular weight within the above range, it can have good stability, so during extrusion or injection molding, curing is unlikely to occur depending on the reaction between resins.

The polyamide resin having a benzene ring as a part of its main chain may be prepared through condensation polymerization of dicarboxylic acid comprising about 10 to about 100 mole % of aromatic dicarboxylic acid and a monomer comprising an aliphatic and/or alicyclic diamine. The aliphatic and/or alicyclic diamine monomer can have 4 to 20 carbon atoms, and the aromatic dicarboxylic acid monomer can comprise terephthalic acid and/or isophthalic acid. Exemplary polyamide resins including a benzene ring as a part of their main chain can include units derived from an aromatic dicarboxylic acid such as illustrated in Chemical Formulas 10 and/or 11.

[chemical structure]

Examples of the polyamide resin having a benzene ring as a part of its main chain can include without limitation resins of Chemical Formula 12 below, such as PA6T (m=6) and/or PA10T (m=10):

[chemical structure]

wherein m is an integer from 4 to 12, and n is an integral from 50 to 500.

PA6T (m=6) may be prepared by condensation polymerization of hexamethylene diamine and terephthalic acid, and PA10T (m=10) may be prepared by condensation polymerization of 1,10-decane diamine and terephthalic acid.

Other examples of a polyamide resin having a benzene ring as a part of its main chain can include without limitation polytetramethylene adipamide (PA46), polycaproamide/polyhexamethylene terephthalamide copolymer (PA6/6T), polyhexamethylene adipamide/polyhexamethylene terephthalamide copolymer (PA66/6T), polyhexamethylene adipamide/polyhexamethylene isophthalamide copolymer (PA66/6I), polyhexamethylene terephthalamide/polyhexamethylene isophthalamide copolymer (PA6T/6I), polyhexamethylene terephthalamide/polydodecanamide copolymer (PA6T/12), polyhexamethylene adipamide/polyhexamethylene terephthalamide/polyhexamethylene isophthalamide copolymer (PA66/6T/6I), polyxylylene adipamide (PAMXD6), polyhexamethylene terephthalamide/poly(2-methylpentamethylene terephthalamide) copolymer (PA6T/M5T), polynonamethylene terephthalamide (PA9T), polydecamethylene terephthalamide (PA10T), and the like, and combinations thereof.

The crystalline thermoplastic resin (A) may further comprise a liquid crystal polymer. In this case, the thermoplastic resin composition of the present invention can have excellent heat resistance. Examples of the liquid crystal polymer can include without limitation para-azoxyanisole (PAA), para-methoxybenzylidene-para-butylaniline (MBBA), terephthalic acid (TA), para-hydroxybenzoic acid (HBA), hydroquinone (HQ), 6-hydroxy-2-naphtoic acid (HNA) and the like, and combinations thereof.

The thermoplastic resin composition may include the crystalline thermoplastic resin (A) in an amount of about 50 to about 90% by weight based on 100% by weight of crystalline thermoplastic resin (A) and filler in which a carbon nanostructure is grown on a glass fiber surface (B). In some embodiments, the thermoplastic resin composition can include the crystalline thermoplastic resin (A) in an amount of about 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90% by weight. Further, according to some embodiments of the present invention, the crystalline thermoplastic resin (A) may be present in an amount of from about any of the foregoing amounts to about any other of the foregoing amounts.

If the amount of the crystalline thermoplastic resin (A) is less than about 50% by weight, fluidity and injection moldability can be deteriorated. If the amount of the crystalline thermoplastic resin (A) is more than about 90% by weight, effectiveness of EMI shielding property can be deteriorated.

### (B) Filler in which a Carbon Nanostructure is Grown on a Glass Fiber Surface

In order to improve effectiveness of EMI shielding property, a filler in which a carbon nanostructure is grown on a glass fiber surface may be used in the present invention. The carbon nanostructure can have excellent EMI shielding property; however, when it is used alone, desired EMI shielding property cannot be achieved due to poor dispersibility of the carbon nanostructure.

Also, a carbon fiber can have good dispersibility due to its long length, so a network between carbon fibers can be formed easily. However, in order to achieve desired EMI shielding property, carbon fiber should be used in high amounts, which can deteriorate fluidity, injection moldability and/or mechanical properties.

Therefore, in the present invention, the filler in which a carbon nanostructure is grown on a glass fiber surface may be used. The glass fiber thereof can form a network easily due to its good dispersibility and it has less warpage, and the carbon nanostructure thereof has excellent EMI shielding property. Accordingly, using only small amount of the carbon nanostructure, fluidity, injection moldability and/or mechanical properties can be improved and desired EMI shielding property can be achieved.

The glass fiber used in filler (B) can be a glass fiber as known in the art. The glass fiber can be one that is available commercially, and/or it may be prepared by conventional methods. The glass fiber may have an average length of about 0.1 to about 30 mm, and an average diameter of about 1 to about 30 μm. When the glass fiber has an average length and average diameter within the above ranges, the glass fiber can have excellent dispersibility.

The cross section of the glass fiber is not limited, and a glass fiber having a circular, oval, square, rectangular and/or amorphous cross section may be used. In exemplary embodiments, the ratio of the minor axis of the cross section to the major axis of the cross section is about 1:1.5 to about 1:10. A glass fiber may prevent warpage of the thermoplastic resin.

Carbon-based and/or graphite-based carbon nanostructures may be used as the carbon nanostructure. Examples of the carbon-based carbon nanostructure can include without limitation carbon powders, carbon (minute) particles, carbon black, carbon fibers, carbon nanotubes and the like, and combinations thereof. In exemplary embodiments, carbon nanotubes may be used. The carbon nanostructure has an average length of about 1 to about 1000 μm and an average diameter of about 1 to about 100 nm. When the carbon nanostructure has an average length and an average diameter within the above ranges, the carbon nanostructures may easily form a network between themselves.

Examples of methods for synthesizing carbon nanotubes can include without limitation arc-discharge, pyrolysis, laser vaporization, plasma chemical vapor deposition, thermal chemical vapor deposition, electrolysis, flame synthesis method and the like. In the present invention, carbon nanotubes prepared by any method may be used.

Carbon nanotubes can be classified as single wall carbon nanotubes, double wall carbon nanotubes, multi wall carbon nanotubes, and/or cup-stacked carbon nanofibers with multi layered truncated graphenes and a hollow tubular form, depending, for example, on the number of walls and/or the shape of the carbon nanotubes. The types of the carbon nanotubes that may be used are not limited. In exemplary embodiments, double wall carbon nanotubes and/or multi wall carbon nanotubes may be used, which can provide advantages in terms of productivity.

The filler in which a carbon nanostructure is grown on a glass fiber surface (B) comprises about 60 to about 95% by weight of the glass fiber and about 5 to about 40% by weight of the carbon nanostructure.

In some embodiments, the filler can include the glass fiber in an amount of about 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, or 95% by weight. Further, according to some embodiments of the present invention, the glass fiber may be present in an amount of from about any of the foregoing amounts to about any other of the foregoing amounts.

In some embodiments, the filler can include the carbon nanostructure in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or 40% by weight. Further, according to some embodiments of the present invention, the carbon nanostructure may be present in an amount of from about any of the foregoing amounts to about any other of the foregoing amounts.

When the filler includes the glass fiber and the carbon nanostructure in amounts within the above ranges, the filler can form a good network, so fluidity may be not deteriorated and EMI shielding property may be improved.

The thermoplastic resin composition may include the filler in which a carbon nanostructure is grown on a glass fiber surface (B) may be included in an amount of about 10 to about 50% by weight based on 100% by weight of the crystalline thermoplastic resin (A) and the filler in which carbon nanostructure is grown on a glass fiber surface (B). In some embodiments, the thermoplastic resin composition may include the filler in an amount of about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50% by weight. Further, according to some embodiments of the present invention, the filler may be present in an amount of from about any of the foregoing amounts to about any other of the foregoing amounts.

If the amount of the filler in which a carbon nanostructure is grown on a glass fiber surface (B) is less than about 10% by weight, EMI shielding property may be deteriorated. If the amount of the filler in which a carbon nanostructure is grown on a glass fiber surface (B) is more than about 50% by weight, desired resin composition may be not achieved because extrusion may not happen.

### (C) Conductive Additives

In order to improve EMI shielding property of the thermoplastic resin, the thermoplastic resin may further comprise a conductive additive. Examples of the conductive additive may include without limitation magnetic materials, dielectric materials, conductive materials, and the like, and combinations thereof.

Conductive materials absorb electric wave by current which flows on a resistor, resistance wire, resistance film, and the like. Examples of the magnetic materials can include without limitation ferrite, and the like. Examples of the dielectric materials can include without limitation carbon, carbon-containing expandable urethane, carbon-containing expandable polystyrene, and the like. The conductive additives (C) are known in the art, are commercially available, and also may be prepared by conventional methods.

The thermoplastic resin composition may include the conductive additives (C) in an amount of 0 to about 60 parts by weight based on the about 100 parts by weight of the crystalline thermoplastic resin (A) and the filler in which a carbon nanostructure is grown on a glass fiber surface (B). In some embodiments, the thermoplastic resin composition may include the conductive additives (C) in an amount of 0 (no conductive additive is present), about 0 (conductive additive is present), 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, or 60 parts by weight. Further, according to some embodiments of the present invention, the conductive additive may be present in an amount of from about any of the foregoing amounts to about any other of the foregoing amounts.

When the amount of the conductive additive (C) is more than about 60 parts by weight, fluidity, injection moldability and mechanical properties may be deteriorated.

### (D) Other Additives

The thermoplastic resin composition of the present invention may further comprise one or more other additives. Examples of the additives may include without limitation antimicrobials, releasing agents, heat stabilizers, antioxidants, photostabilizers, compatibilizers, dyes, inorganic additives, surfactants, nucleating agents, coupling agents, plasticizers, impact modifiers, admixtures, colorants, stabilizers, lubricants, antistatic agents, pigments, flame proofing agents, and the like, and combinations thereof depending on the desired properties of the end product and its intended use.

The thermoplastic resin composition having excellent EMI shielding property may be prepared using any suitable conventional method to prepare a resin composition. For example, components of the present invention and other optional additives may be mixed at the same time, and injection and extrusion molding article can be prepared from the composition.

EMI shielding articles in accordance with the present invention may be prepared from the thermoplastic resin composition.

The EMI shielding articles of the present invention may have an EMI shielding ratio of about 20 to about 85 dB measured for 2 mm thickness in accordance with ASTM D 4935.

The EMI shielding article of the present invention may have about 100 to about 250 mm of spiral fluidity measured for 1 mm thickness and 1 μm width at a barrel temperature of 320° C. and a mold temperature of 140° C.

The present invention will be further defined in the following examples, which are intended for the purpose of illustration and are not to be construed as in any way limiting the scope of the present invention.

### EXAMPLES

The particulars of each component used in Examples and Comparative Examples of the present invention are as follows:

### (A) Crystalline Thermoplastic Resin

(a1) Polyphenylene sulfide resin (Product name: PPS-hb DL) manufactured by Deokyang Corporation is used.

(a2) Polyphenylene sulfide resin prepared by blending 100 parts by weight of polyphenylene sulfide resin, which is manufactured by Deokyang Corporation, and 30 parts by weight of liquid crystal polymer (Product name: S6000), which is manufactured by Sumitomo Corporation, is used.

### (B) Filler in which a Carbon Nanostructure is Grown on a Glass Fiber Surface

(b1) Filler in which a carbon nanostructure having an average length of 70 μm and an average diameter of 10 nm is grown on a glass fiber surface having an average length of 3 mm and an average diameter of 13 μm manufactured by Owens Corning Corporation is used.

(b2) Filler in which a carbon nanostructure is grown on a glass fiber surface is used, wherein the glass fiber is flat and has an average length of 3 mm, an average diameter (large diameter) of 28 μm, and a ratio of minor axis of cross section to major axis of cross section is 1:4, and the carbon nanostructure has an average length of 70 μm and an average diameter of 10 nm.

(b3) Filler (Product name: NC7000) manufactured by Nanocyl Corporation is used, having an average diameter of 10 nm, an average length of 20 μm, and an aspect ratio of 2000.

(b4) Carbon black (Product name: ENSACO 250G) manufactured by Timcal Corporation is used.

(b5) Ketjen black (Product name: EC-300J) manufacture by Mitsubishi Corporation is used.

(b6) Carbon fiber (Product name: TENAX A HT C493) manufactured by Teijin Corporation is used, having an average length of 6 mm and an average diameter of 7 μm.

(b7) Steel fiber having an average length of 3 mm and an average diameter of 10 μm is used as filler.

### Examples 1 to 4 and Comparative Examples 1 to 6

The crystalline thermoplastic resin (A), filler (B), and additives, i.e. wax and antioxidant, are mixed in the amounts set forth in the following Table 1 in a conventional mixer. After dry mixing, the composition is placed into a twin-screw extruder having L/D=45 and Φ=44 mm, and then extruded to form pellets. After the pellets are dried in a heated-air dryer at 100° C. for 4 hours, specimens for evaluating the physical properties are prepared using a 15 oz injection molding machine at an injection temperature of 300° C. The properties are measured after leaving the specimens at a temperature of 23° C. and a relative humidity of 50% for 48 hours.

In following Table 1, the mixture ratio of (A) and (B) is represented by % by weight based on 100% by weight of (A) and (B).

TABLE 1

| | | Examples | | | | Comparative Examples | | | | | |
|---|---|---|---|---|---|---|---|---|---|---|---|
| | | 1 | 2 | 3 | 4 | 1 | 2 | 3 | 4 | 5 | 6 |
| (A) | (a1) | 50 | 70 | — | 50 | 90 | 50 | 50 | 50 | 60 | 70 |
| | (a2) | — | — | 50 | — | — | — | — | — | — | — |
| (B) | (b1) | 50 | 30 | 50 | — | — | — | — | — | — | — |
| | (b2) | — | — | — | 50 | — | — | — | — | — | — |
| | (b3) | — | — | — | — | 10 | — | — | — | — | — |
| | (b4) | — | — | — | — | — | 50 | — | — | — | — |
| | (b5) | — | — | — | — | — | — | 50 | — | — | — |
| | (b6) | — | — | — | — | — | — | — | 50 | 40 | — |
| | (b7) | — | — | — | — | — | — | — | — | — | 30 |

The physical properties for the specimens are evaluated and the results are shown in the following Table 2.

### Methods for Evaluation of Physical Properties

(1) EMI Shielding Ratio (dB): EMI shielding ratio is measured for thickness of 2 mm in accordance with ASTM D4935.

(2) Spiral Fluidity (mm): Spiral fluidity is measured for 1 mm thickness and 1 μm width at a barrel temperature of 320° C. and a mold temperature of 140° C.

(3) Izod Impact Strength (J/m): Izod impact strength is measured for a ⅛″ thick specimen in accordance with ASTM D256.

(4) Flexural Modulus (GPa): Flexural modulus is measured at velocity 2.8 mm/min in accordance with ASTM D790.

(5) Warpage: Warpage is measured after leaving a specimen having dimensions of 100 mm×100 mm×1 mm at a temperature of 25° C. and relative humidity of 50% for 24 hours under constant temperature and constant humidity, then fixing 3 points, and then measuring the gap at one point using vernier calipers. The warpage is evaluated based on the following scale:

⊚-good, O-average, X-bad

TABLE 2

| | Examples | | | | Comparative Examples | | | | | |
|---|---|---|---|---|---|---|---|---|---|---|
| | 1 | 2 | 3 | 4 | 1 | 2 | 3 | 4 | 5 | 6 |
| EMI Shielding | 85 | 61 | 85 | 87 | 10 | 10 | 26 | 45 | 37 | 39 |
| Ratio | | | | | | | | | | |
| Spiral | 142 | 162 | 150 | 154 | 87 | 75 | 66 | 75 | 86 | 47 |
| fluidity | | | | | | | | | | |
| Izod Impact | 75 | 64 | 52 | 75 | 22 | 21 | 27 | 120 | 101 | 34 |
| Strength | | | | | | | | | | |
| Flexural | 12 | 9.2 | 14 | 13 | 5 | 4.8 | 4.9 | 26 | 18 | 11 |
| Modulus | | | | | | | | | | |
| Warpage | ◯ | ◯ | ◯ | □ | ◯ | ◯ | ◯ | X | X | X |

As shown in Table 2, Examples 1 to 4 using the filler in which a carbon nanostructure is grown on a glass fiber surface (B) have excellent EMI shielding property, fluidity and mechanical property. In addition, Example 3 which further includes a liquid crystal polymer has better fluidity compared with Example 1, and Example 4 including a flat glass fiber has good flexure property.

In contrast, Comparative Examples 1 to 6 including carbon nanotubes, conductive carbon black, carbon fiber and metal fiber as EMI shielding filler have deteriorated EMI shielding property, fluidity and mechanical property compared with Examples 1 to 4.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that d\modifications and other embodiments are intended to be included within the scope of the appended claims. Although specific terms are employed herein, they are used in generic and descriptive sense only and not for purposes on limitation of the scope of the invention being defined in the claims.

What is claimed is:

1. A thermoplastic resin composition with excellent EMI shielding property comprising (A) about 50 to about 90% by weight of a crystalline thermoplastic resin having a melting point of about 200 to about 380° C.; and (B) about 10 to about 50% by weight of a filler in which a carbon nanostructure having an average length of about 1 to about 1000 μm and an average diameter of about 1 to about 100 nm is grown on a glass fiber surface.

2. The thermoplastic resin composition having excellent EMI shielding property of claim 1, wherein the crystalline thermoplastic resin (A) is polyphenylene sulfide resin, polyamide resin having benzene ring as a part of its main chain, or a combination thereof.

3. The thermoplastic resin composition having excellent EMI shielding property of claim 2, wherein the crystalline thermoplastic resin (A) further comprises a liquid crystal polymer.

4. The thermoplastic resin composition having excellent EMI shielding property of claim 3, wherein the liquid crystal polymer comprises para-azoxyanisole (PAA), para-methoxybenzylidene-para-butylaniline (MBBA), terephthalic acid (TA), para-hydroxybenzoic acid (HBA), hydroquinone (HQ), 6-hydroxy-2-naphtoic acid (HNA) or a combination thereof.

5. The thermoplastic resin composition having excellent EMI shielding property of claim 1, wherein the glass fiber has an average length of about 0.1 to about 30 mm and an average diameter of about 1 to about 30 μm.

6. The thermoplastic resin composition having excellent EMI shielding property of claim 1, wherein the glass fiber has a ratio of the minor axis of the cross section to the major axis of the cross section ratio of about 1:1.5 to about 1:10.

7. The thermoplastic resin composition having excellent EMI shielding property of claim 1, wherein the carbon nanostructure includes a carbon nanotube.

8. The thermoplastic resin composition having excellent EMI shielding property of claim 1, wherein the filler comprises about 60 to about 95% by weight of the glass fiber and about 5 to about 40% by weight of the carbon nanostructure.

9. The thermoplastic resin composition having excellent EMI shielding property of claim 1 further comprising magnetic materials, dielectric materials, conductive materials or a combination thereof.

10. The thermoplastic resin composition having excellent EMI shielding property of claim 1 further comprising one or more additives selected from the group consisting of antimicrobials, releasing agents, heat stabilizers, antioxidants, photostabilizers, compatibilizers, dyes, inorganic additives, surfactants, nucleating agents, coupling agents, plasticizers, impact modifiers, admixtures, colorants, stabilizers, lubricants, antistatic agents, pigments, flame proofing agents and combinations thereof.

11. An EMI shielding article prepared from the thermoplastic resin composition in accordance with claim 1.

12. The EMI shielding article of claim 11, wherein the EMI shielding article has EMI shielding ratio of about 20 to about 85 dB measured for 2 mm thickness in accordance with ASTM D 4935.

13. The EMI shielding article of claim 11, wherein the EMI shielding article has spiral fluidity of about 100 to about 250 measured for 1 mm thickness and 1 μm width at a barrel temperature of 320° C. and a mold temperature of 140° C.
